(19) United States
(12) Patent Application Publication
(10) Pub. No.: US 2008/0231277 A1
(43) Pub. Date: Sep. 25, 2008

(54) NMR spectrometer

(76) Inventors: Hiroyuki Yamamoto, Kokubunji (JP); Kazuo Saitoh, Kodaira (JP); Haruhiro Hasegawa, Sendai (JP); Masaya Takahashi, Hitachinaka (JP); Michiya Okada, Mito (JP)

Correspondence Address: REED SMITH LLP;Suite 1400, 3110 Fairview Park Drive, Falls Church, VA, 22042, US

(21) Appl. No.: 12/010,292

(22) Filed: Jan. 23, 2008

(30) Foreign Application Priority Data
Mar. 23, 2007 (JP) 2007-076822

(51) Int. Cl. G01R 33/31

(52) U.S. Cl. 324/318

(57) ABSTRACT

The present invention provides a highly-sensitive nuclear magnetic resonance (NMR) spectrometer which achieves a high Q factor using a superconductor, and concurrently which is provided with a probe antenna maintaining the magnetic homogeneity of the static magnetic field in a sample space. An antenna coil is fabricated by using a wire having a superconducting layer formed on the surface of a metal wire.

### CLAIM OF PRIORITY

The present application claims priority from Japanese application JP 2007-076822 filed on Mar. 23, 2007, the content of which is hereby incorporated by reference into this application.

### BACKGROUND OF THE INVENTION

1. Field of the Invention

The present invention relates to a nuclear magnetic resonance spectrometer (hereinafter referred to simply as an “NMR spectrometer”), and more particularly to an NMR spectrometer characterized by a probe antenna that is used for applying a radio-frequency signal at a predetermined resonance frequency to a sample placed in a uniform magnetic field, and/or for receiving a free induction decay signal (or an FID signal).

2. Description of the Related Art

Nuclear magnetic resonance (NMR) spectrometry is a measurement approach that is capable of obtaining information on a substance at the atomic level, and hence that is excellent for observation of the structure of a compound. The fundamental principle of the measurement is to apply a radio-frequency magnetic field to a sample placed in a static magnetic field, and to then receive and analyze a response signal from the excited nuclear spin. An NMR spectrometer having a superconducting electromagnet capable of producing a homogeneous high magnetic field (B₀) is used for high-resolution measurement. Currently, a 21.6-T (or equivalently, 920-MHz) NMR spectrometer is made for the purpose mainly of analyzing a three-dimensional structure of proteins or doing the like.

A small amount of sample for use in protein analysis produces a free induction decay signal (hereinafter referred to simply as an “FID signal”) of feeble intensity. Thus, a probe for receiving the FID signal requires high sensitivity. A reduction in thermal noise involved in signal detection is effective for an improvement in a signal-to-noise ratio (or an S/N ratio) that is used as an index of sensitivity of the NMR spectrometry. A known method for the noise reduction is to cool the probe to a low temperature, and such a probe is called a “cryogenic probe.” An example of the cryogenic probe is disclosed in U.S. Pat. No. 5,247,256. Also, the signal intensity depends on the quality factor (hereinafter referred to simply as the “Q factor”) of a probe antenna, and thus, the probe antenna is required to have a high Q factor in order to achieve highly-sensitive NMR measurement. Since the Q factor depends on a resistive loss in the probe antenna, an effective means for improving the Q factor is either: to use a member of a low resistance for a conductor to constitute the probe antenna; to cool the conductor to a low temperature and thereby reduce its resistance; or to employ a superconductor of extremely low resistance, as compared with a normal metal, for the conductor used for the probe antenna. Examples of the use of a superconductor for the probe antenna are disclosed in U.S. Pat. No. 5,585,723, US Patent Application Publication No. 2003-0052682, WO/01/94964, and so on.

### SUMMARY OF THE INVENTION

Using the superconductor having an extremely small resistive loss to form the probe antenna enables an increase in the Q factor of the antenna and hence an improvement in the sensitivity of the NMR spectrometry. However, the probe antenna using the superconductor has the large problem that the magnetic homogeneity of a static magnetic field in a test sample space is disturbed due to the diamagnetic effect, which is characteristic of the superconductor. The occurrence of disturbance of the static magnetic field in the sample space leads to expansion of a measured NMR spectral line width and hence a reduction in the signal intensity. This results in a decrease in the sensitivity of the spectrometry (that is, the S/N ratio). Therefore, the probe antenna made of a bulk superconductor, a conventional superconducting multi-core wire material, or the like has difficulty in being applied to a high-sensitivity NMR spectrometer, due to the superconductor of great volume and hence a significant impairment in the magnetic homogeneity of the static magnetic field. In such a probe antenna using a superconducting thin film as disclosed in U.S. Pat. No. 5,585,723, US Patent Application Publication No. 2003-0052682 and WO/01/94964, it is possible to suppress the disturbance of the static magnetic field due to the superconductor, by reducing the volume of the superconductor. However, the probe antenna has the problem that the magnetic homogeneity of the static magnetic field deteriorates due to a magnetic moment produced by a dielectric substrate. This problem occurs because the dielectric substrate, such as sapphire having the superconducting thin film formed thereon, is of great volume. In addition, plural dielectric planar substrates having superconducting thin film patterns formed thereon are discretely disposed in the vicinity of the sample in order to achieve a three-dimensional antenna configuration around a sample tube. With this arrangement, it is very difficult to use shimming to ensure the magnetic homogeneity, because a distribution pattern of an error magnetic field in the sample space becomes complicated.

An object of the present invention is therefore to provide a high-sensitivity NMR spectrometer having a superconducting probe antenna that achieves a high Q factor and prevents deterioration in magnetic homogeneity of a static magnetic field in a sample space.

The present invention employs the following configuration in order to achieve a highly-sensitive NMR spectrometer.

Firstly, a superconducting magnet is used in order to produce a uniform high magnetic field (B₀). In addition, a probe antenna is provided at the region of the uniform high magnetic field in the superconducting magnet. The probe antenna applies, to a sample, a radio-frequency signal at a resonance frequency of the nuclear spin, and also receives a response signal from the nuclear spin. Moreover, provided is a cooling system including a cryocooler, a cold gas line, and a heat exchanger, in order to cool the probe antenna. He gas cooled to low temperature by the cryocooler is caused to circulate through the cold gas line installed inside the probe, so that the heat exchanger disposed at the tip of the probe is cooled. The probe antenna is thermally connected to the heat exchanger, thus being cooled by heat transfer.

In the present invention, the probe antenna is formed by using a wire having a superconducting layer of a thickness from several hundred nm to several μm formed on the surface of a metal wire. The probe antenna is fixed by being wound around a cylindrical bobbin made of a dielectric. The probe antenna is an LC resonant circuit, and a radio-frequency current flows to the conductor of the antenna upon detection of a signal from the sample. At this time, the flowing radio-frequency current converges to the surface of the conductor of the antenna due to the conductor skin effect. For this reason, it is possible to reduce a resistive loss in the entire antenna, and to thus improve a Q factor, by forming a superconducting thin film of a low resistance on the surface of the conductor of the antenna.

According to the present invention, it is possible to reduce a resistive loss in the entire antenna, and to thus improve a Q factor. This is achieved by forming a superconducting thin film of a low resistance disposed on the surface of a conductor for the antenna which a radio-frequency current converges to and passes through upon detection of a signal.

In addition, the volume of the superconducting layer formed on the surface of the metal wire is very small. Accordingly, it is possible to significantly suppress disturbance of the static magnetic field due to the diamagnetic property of the superconductor, as compared with a conventional antenna formed by using a superconducting wire or a superconducting bulk. Moreover, in the present invention, the antenna is formed by winding, around a dielectric cylindrical bobbin, a composite metal wire fabricated by forming the superconductor on the metal wire. This configuration eliminates the need for a dielectric substrate used for formation of a superconducting thin film, as in the case of a conventional probe antenna using a superconducting thin film. As a result, it is possible to greatly reduce the volume of a dielectric to be used, as compared with the conventional superconducting thin film probe antenna.

In addition, the present invention makes it possible to achieve a smaller magnetic susceptibility of the metal wire forming the superconductor than that of a dielectric substrate. Concurrently, the present invention also makes it possible to achieve a smaller volume necessary for the configuration of the antenna than that of the dielectric substrate used in the conventional superconducting thin film probe antenna. As a result, according to the configuration of the present invention, it is possible to suppress a magnetic moment induced by members other than the super conductor required for the antenna configuration, as compared with the configuration of the conventional superconducting thin film probe antenna. Moreover, in the conventional superconducting thin film probe antenna, plural dielectric substrates are discretely disposed in a uniform magnetic field space. By contrast, in the present invention, the antenna can be formed by using a single cylindrical bobbin of excellent symmetry. With this antenna configuration, a distribution pattern of an error magnetic field by the dielectric is simplified, and it becomes easy to ensure the magnetic homogeneity by shimming.

As described above, the reduction in volume and the improvement in shape of the dielectric make it possible to suppress disturbance of the static magnetic field to a level enabling a highly-sensitive NMR measurement. Here, the disturbance occurs due to members other than the superconductor, which constitute the antenna. Accordingly, the present invention makes it possible to achieve a probe antenna having a very high Q factor resulting from the distinctive low loss property of a superconductor. Concurrently, the present invention makes it possible to achieve the probe antenna capable of maintaining the magnetic homogeneity of a static magnetic field in a sample space. As a result, it is possible to achieve an improvement in signal detection sensitivity in an NMR measurement.

### BRIEF DESCRIPTION OF THE DRAWINGS

FIGS. 1 A and 1B schematically show the configuration of an NMR spectrometer which produces a uniform magnetic field in the horizontal direction.

FIG. 2 schematically shows a cross-sectional structure of a wire for an antenna coil.

FIGS. 3A and 3B are schematic views of a solenoidal-shaped probe antenna according to a first embodiment.

FIGS. 4A and 4B are schematic views of a solenoidal-shaped probe antenna according to a second embodiment.

FIG. 5 is a schematic view of a solenoidal-shaped probe antenna according to a third embodiment.

FIGS. 6A and 6B schematically show the configuration of an NMR spectrometer which produces a uniform magnetic field in the vertical direction.

FIGS. 7A and 7B are schematic views of a saddle-shaped probe antenna according to a fourth embodiment.

FIG. 8 is a schematic view of a birdcage-shaped probe antenna according to a fifth embodiment.

FIG. 9 schematically shows a cross-sectional structure of a wire for an antenna coil according to a sixth embodiment.

FIG. 10 schematically shows a cross-sectional structure of a wire for an antenna coil according to a seventh embodiment.

FIG. 11 schematically shows a cross-sectional structure of a wire for an antenna coil according to an eighth embodiment.

FIG. 12 schematically shows a cross-sectional structure of a wire for an antenna coil according to a ninth embodiment.

FIG. 13 schematically shows a cross-sectional structure of a wire for an antenna coil according to a tenth embodiment.

### DETAILED DESCRIPTION OF THE PREFERRED EMBODIMENTS

A probe antenna of an NMR spectrometer of the present invention is characterized by having a construction including an antenna coil made of a metal wire or metal foil and a superconducting layer formed on the surface of the antenna coil. Embodiments of the present invention will be described in detail below with reference to the drawings.

### First Embodiment

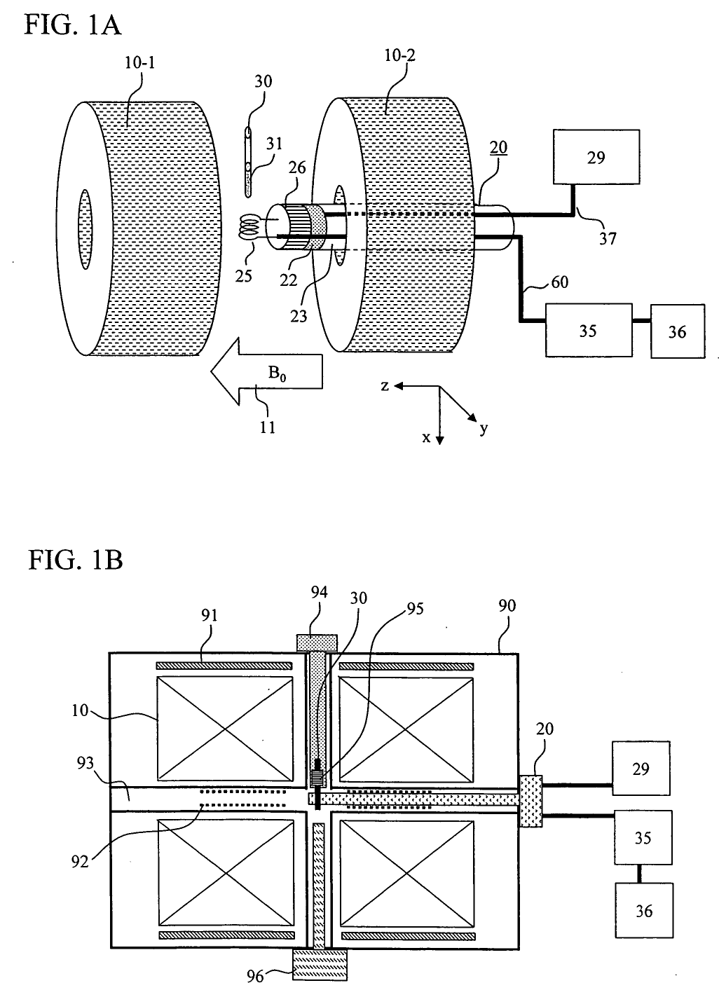

FIG. 1A is a perspective view showing the general configuration and arrangement of a principal constituent part of an NMR spectrometer to which the present invention is applied. Two separate superconducting magnets 10-1 and 10-2 produce a uniform magnetic field (that is, a uniform static magnetic field) 11 along the central axis. This uniform magnetic field 11 is indicated by the arrow B₀ in FIG. 1A. A sample tube 30 with a sample 31 housed therein is inserted from a direction perpendicular to the uniform magnetic field (e.g., the direction of the x-axis in FIG. 1A). A cryogenic probe 20 incorporating a solenoidal-shaped probe antenna 25 that detects a signal from the sample 31 is inserted in the same direction as that of the uniform magnetic field. The cryogenic probe 20 is constituted of the probe antenna 25, a heat exchanger 22, a cold gas line 37, a probe tip stage 26, and a probe housing 23. The heat exchanger 22 is provided at the end portion of a cryocooler 29 that acts as a cold source. Through the cold gas line 37, helium (He) gas cooled by the cryocooler 29 is circulated to cool the heat exchanger 22. The probe tip stage 26 is cooled by the heat exchanger 22. The probe antenna 25, the heat exchanger 22, the cold gas line 37, and the probe tip stage 26 are connected with one another in the probe housing 23. In addition, a spectrometer 35 transmits a radio-frequency signal (hereinafter referred to simply as an “RF signal”) to the probe antenna 25 through a signal line 60, then receives and analyzes an RF signal sent from the sample 31, and outputs the result of measurement to a display device 36, which in turn displays the result. Moreover, an unillustrated gradient coil for producing a gradient magnetic field in a sample space is disposed outside the probe antenna 25.

FIG. 1B is a schematic view showing in more detail the principal constituent part of the NMR spectrometer to which the present invention is applied. The superconducting magnet 10 is installed in a cryostat 90 filled with liquid helium, and a superconducting shim coil 91 for correcting the static magnetic field is disposed around the outer side of the superconducting magnet 10. A cross-shaped bore 93 is provided in the cryostat 90 for the magnet, while a room-temperature shim coil 92 is provided inside the bore 93. In addition, in the cryostat 90, a sample rotating system 94 is installed in a direction perpendicular to the bore 93, and a spinner 95 holding the sample tube 30 is inserted inside the sample rotating system 94. The sample rotating system 94 rotates the sample tube 30 by blowing gas against the spinner 95. Moreover, a sample temperature controlling system 96 for regulating the temperature of the sample 31 by feeding a temperature regulating gas is installed from under the bore.

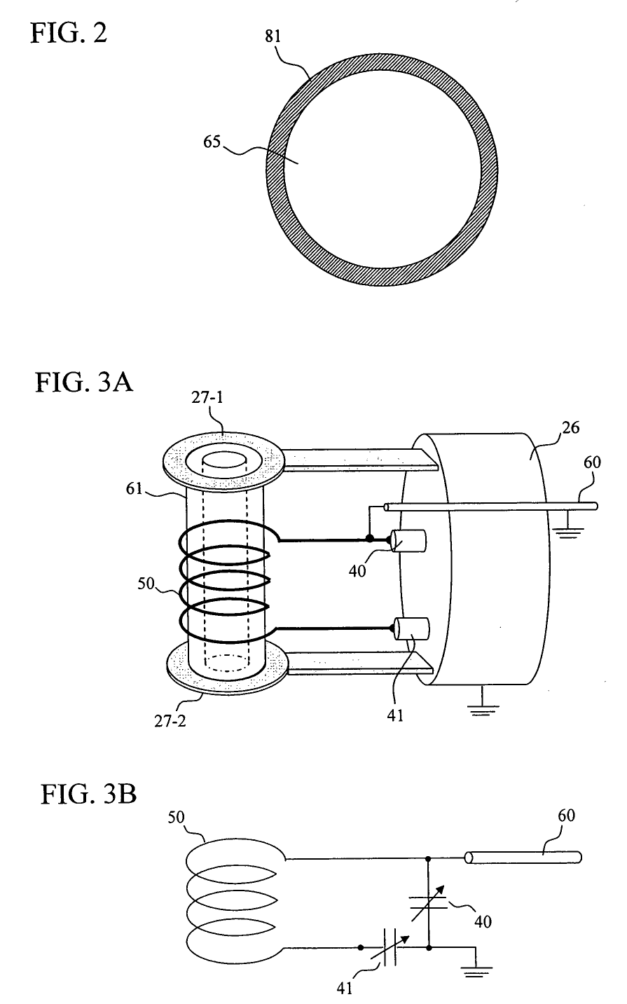

FIG. 2 schematically shows a cross-sectional structure of a wire that constitutes the probe antenna according to the first embodiment. The wire has a double-layer structure formed of a metal wire 65 that is a base material, and a superconducting layer 81. The metal wire 65 is made of copper (Cu). The copper is molded into a solenoidal-shaped antenna coil, and then a superconducting thin film made of magnesium diboride (MgB₂) is formed to have a thickness of 1 μm on the surface of the antenna coil by evaporation method.

FIG. 3A is a perspective view schematically showing the solenoidal-shaped antenna coil fabricated by use of the wire shown in FIG. 2, and mounted on the cryogenic probe 20. FIG. 3B schematically shows electrical connection of the probe antenna. A cylindrical bobbin 61 is fixed between two support plates 27-1 and 27-2, and an antenna coil 50 is wound around the cylindrical bobbin 61. The coil 50 is connected, at a first end thereof, to a matching trimmer capacitor 40 and the signal line 60, and is also connected, at a second end thereof, to a tuning trimmer capacitor 41. Electrodes, having no connections to the antenna coil 50, of the respective trimmer capacitors 40 and 41, and a coating on the signal line 60 are electrically and mechanically connected to the metallic probe tip stage 26 that acts as a ground. The capacitances of the two trimmer capacitors 40 and 41 are adjusted so that the impedance of the antenna at its resonance peak can be matched to 50Ω at a predetermined resonance frequency. The support plates 27-1 and 27-2 and the cylindrical bobbin 61 are made of sapphire (Al₂O₃). In the first embodiment, the thickness of the wire for the antenna coil 50 is set to 1 mm, the diameter of the antenna coil 50 is set to 8 mm, and the number of turns of the antenna coil 50 is set to four.

The probe tip stage 26 is cooled to low temperature by being thermally connected to the heat exchanger 22 at the end of the cryocooler 29 that acts as the cold source, which is not shown in FIG. 3A. Additionally, the probe tip stage 26, the support plates 27-1 and 27-2, and the cylindrical bobbin 61 are likewise thermally connected to one another. Accordingly, the antenna coil 50 is cooled to the cryogenic temperature by heat transfer through the cylindrical bobbin 61 and the support plates 27-1 and 27-2.

In the probe antenna according to the first embodiment, the superconducting thin film of a low resistance is disposed on the surface of the wire for the antenna coil which a radio-frequency current converges to and passes through upon detection of a signal. With this configuration, it is possible to reduce a resistive loss, and to thus improve a Q factor, as compared with an antenna coil using a normal conductor.

In addition, the dielectric (the sapphire bobbin) used in the first embodiment can be greatly reduced in volume as compared with a dielectric (including a sapphire substrate and a support member for fixing the substrate) used in a conventional superconducting thin film probe antenna. Moreover, the magnetic susceptibility of the metal wire (Cu) forming the superconductor is lower than that of a dielectric substrate, and concurrently the volume of the metal wire is sufficiently smaller than that of the dielectric (including the sapphire substrate and the support member for fixing the substrate) used in the conventional superconducting thin film probe antenna. As a result, the configuration of the first embodiment (using the sapphire bobbin and the Cu wire) can greatly suppress a magnetic moment induced by members other than the superconductor required for the antenna configuration, as compared with the configuration of the conventional superconducting thin film probe antenna (using the sapphire substrate, and the support member for fixing the substrate).

Furthermore, in the conventional superconducting thin film probe antenna, plural dielectric substrates are discretely disposed in a uniform magnetic field space. By contrast, in the first embodiment, the antenna can be formed by using a single cylindrical bobbin of excellent symmetry. With this antenna configuration, a distribution pattern of an error magnetic field by the dielectric is simplified, and it becomes easy to ensure the magnetic homogeneity by shimming.

With the above effects, the configuration of the first embodiment can improve the magnetic homogeneity of the static magnetic field in the sample space by one digit, as compared with the conventional superconducting thin film probe antenna. As a result, the present invention makes it possible to provide a probe antenna that has a very high Q factor resulting from the distinctive low loss property of a superconductor, and that prevents impairment of the magnetic homogeneity of the static magnetic field in a sample space.

The resonance characteristics of the probe antenna according to the first embodiment are evaluated in liquid helium (4.2 K). The result of the evaluation shows that the Q value at frequencies of 300 to 600 MHz is improved by a factor of two to four, as compared with the conventional probe antenna made of a normal conductor. Accordingly, using the probe antenna of this configuration for the NMR spectrometer achieves a great improvement in the measurement sensitivity.

In the first embodiment, the MgB₂ thin film is used for the superconducting layer 81 of the wire for the antenna coil. It is obvious that the same result can be obtained also in a similar configuration using, as a superconductor, a Nb alloy (Nb₃Sn or the like), or an oxide high-temperature superconductor such as YBCO. Moreover, it is obvious that a similar configuration may be obtained by using, for the metal wire 65 of the wire for the antenna coil, a diamagnetic metal (Ag, Au, or the like) other than Cu, or a paramagnetic metal (Al, Ta, Pt, Ti, Nb, Rh, or the like). Moreover, although sapphire is used for the cylindrical bobbin 61 and the support plates 27-1 and 27-2 in the first embodiment, it is obvious that aluminum nitride (AlN) may be used instead of the sapphire to obtain the same result.

### Second Embodiment

The second embodiment proposes an NMR spectrometer including a solenoidal-shaped probe antenna, as in the case of the first embodiment. The second embodiment uses a different antenna circuit configuration from that of the first embodiment. The basic configuration of the spectrometer, and the structure of the wire for the antenna coil are the same as those of the first embodiment shown in FIGS. 1A and 1B and FIG. 2.

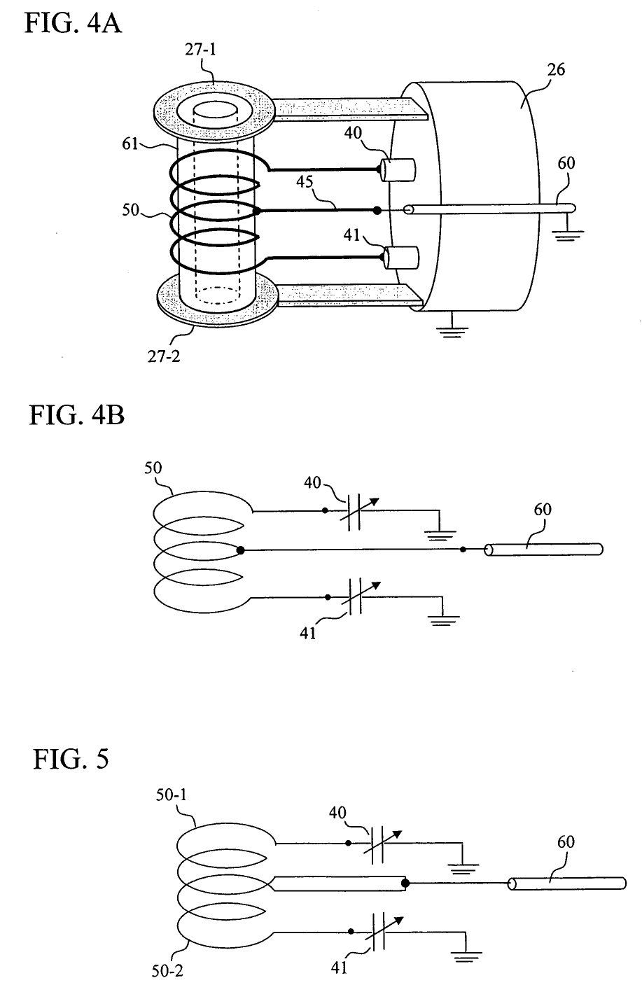

FIG. 4A is a perspective view schematically showing the solenoidal-shaped antenna coil according to the second embodiment mounted on the cryogenic probe 20. FIG. 4B is a view schematically showing an electrical connection of the probe antenna. A Cu wire for 1 mm diameter is wound four turns to be formed into a solenoidal-shaped antenna coil 50. Then, a tap lead 45 made of a Cu wire for 1 mm diameter is connected to a substantially middle point of the antenna coil 50 by a pulse heat bonding method. Thereafter, a superconducting magnesium diboride (MgB₂) thin film of 1 μm thickness is formed on the surfaces of the antenna coil 50 and the tap lead 45 by evaporation method. As shown in FIG. 4A, as in the case of the first embodiment, a cylindrical bobbin 61 is fixed between two support plates 27-1 and 27-2, and the antenna coil 50 is arranged on the cylindrical bobbin 61. The tap lead 45 extending from the middle point of the antenna coil 50 is connected to a signal line 60, and both ends of the antenna coil 50 are connected respectively to trimmer capacitors 40 and 41. Electrodes, having no connections to the antenna coil 50, of the respective trimmer capacitors 40 and 41, and a coating on the signal line 60 are electrically and mechanically connected to a metallic probe tip stage 26 that acts as a ground. The capacitances of the two trimmer capacitors 40 and 41 are adjusted so that the impedance of the antenna at its resonance peak can be matched to 50Ω at a predetermined resonance frequency. The support plates 27-1 and 27-2 and the cylindrical bobbin 61 are made of sapphire (Al₂O₃). In the second embodiment, the diameter of the antenna coil 50 is set to 8 mm.

The probe tip stage 26 is cooled to low temperature by being thermally connected to a heat exchanger at the end of a cryocooler that acts as a cold source, which is not shown in FIG. 4A. Additionally, the probe tip stage 26, the support plates 27-1 and 27-2, and the cylindrical bobbin 61 are likewise thermally connected to one another. Accordingly, the antenna coil 50 is cooled to the cryogenic temperature by heat transfer through the cylindrical bobbin 61 and the support plates 27-1 and 27-2.

In the probe antenna according to the second embodiment, the superconducting thin film of a low resistance is disposed on the surface of the wire for the antenna coil which a radio-frequency current converges to and passes through upon detection of a signal. With this configuration, it is possible to reduce a resistive loss, and to thus improve a Q factor, as compared with an antenna coil using a normal conductor.

In addition, the dielectric (the sapphire bobbin) used in the second embodiment can be greatly reduced in volume as compared with a dielectric (including a sapphire substrate and a support member for fixing the substrate) used in the conventional superconductor thin film probe antenna. Moreover, the magnetic susceptibility of the metal wire (Cu) forming the superconductor is lower than that of a dielectric substrate, and concurrently the volume of the metal wire is sufficiently smaller than that of the dielectric (including the sapphire substrate and the support member for fixing the substrate) used in the conventional superconducting thin film probe antenna. As a result, the configuration of the second embodiment (using the sapphire bobbin and the Cu wire) can greatly suppress a magnetic moment induced by members other than the superconductor required for the antenna configuration, as compared with the configuration of the conventional superconducting thin film probe antenna (using the sapphire substrate and the support member for fixing the substrate).

Furthermore, in the conventional superconducting thin film probe antenna, plural dielectric substrates are discretely disposed in a uniform magnetic field space. By contrast, in the second embodiment, the antenna can be formed by using a single cylindrical bobbin of excellent symmetry. With this antenna configuration, a distribution pattern of an error magnetic field by the dielectric is simplified, and it becomes easy to ensure the magnetic homogeneity by shimming.

With the above effects, the configuration of the second embodiment can improve the magnetic homogeneity of the static magnetic field in the sample space by one digit, as compared with the conventional superconducting thin film probe antenna. As a result, the present invention makes it possible to provide a probe antenna that has a very high Q factor resulting from the distinctive low loss property of a superconductor, and that prevents impairment of the magnetic homogeneity of the static magnetic field in a sample space.

The resonance characteristics of the probe antenna according to the second embodiment are evaluated in liquid helium (4.2 K). The result of the evaluation shows that the Q value at frequencies of 300 to 600 MHz is improved by a factor of two to four, as compared with the conventional probe antenna made of a normal conductor. Accordingly, using the probe antenna of this configuration for the NMR spectrometer achieves a great improvement in the measurement sensitivity.

In the second embodiment, the MgB₂ thin film is used for the superconducting layer 81 of the wire for the antenna coil. It is obvious that the same result can be obtained also in a similar configuration using, as a superconductor, a Nb alloy (Nb₃Sn or the like), or an oxide high-temperature superconductor such as YBCO. Moreover, it is obvious that a similar configuration may be obtained by using, for the metal wire 65 of the wire for the antenna coil, a diamagnetic metal (Ag, Au, or the like) other than Cu, or a paramagnetic metal (Al, Ta, Pt, Ti, Nb, Rh, or the like). Moreover, although sapphire is used for the cylindrical bobbin 61 and the support plates 27-1 and 27-2 in the second embodiment, it is obvious that aluminum nitride (AlN) may be used instead of the sapphire to obtain the same result.

### Third Embodiment

The third embodiment proposes an NMR spectrometer including a solenoidal-shaped probe antenna constituted of a plurality of antenna coils connected to each other. The basic configuration of this spectrometer is the same as those of the first and second embodiments. A wire used for each probe antenna has a structure in which a superconducting layer is formed on the surface of a metal wire as shown in FIG. 2, as in the cases of the first and second embodiments.

FIG. 5 schematically shows electrical connection of the solenoidal-shaped probe antenna according to the third embodiment. A Cu wire for 1 mm diameter, which is a base material for the wire for each antenna coil, is wound two turns to be formed into the solenoidal-shaped antenna coil. Then, a superconducting magnesium diboride (MgB₂) thin film of 1 μm thickness is formed on the surface of the antenna coil by evaporation method. Two two-turn antenna coils 50-1 and 50-2 thus fabricated are disposed to positions where these antenna coils can detect signals from a sample. Then, these antenna coils 50-1 and 50-2 are electrically connected, at first ends thereof, respectively to trimmer capacitors 40 and 41 each of a variable capacitance. In addition, these antenna coils 50-1 and 50-2 are electrically connected, at second ends thereof, to each other, while a signal line 60 is drawn out from the connecting point between these antenna coils 50-1 and 50-2.

In the probe antenna according to the third embodiment, the superconducting thin film of a low resistance is disposed on the surface of the wire for each antenna coil which a radio-frequency current converges to and passes through upon detection of a signal. With this configuration, it is possible to reduce a resistive loss, and to thus improve a Q factor, as compared with an antenna coil using a normal conductor.

In addition, the dielectric (the sapphire bobbin) used in the third embodiment can be greatly reduced in volume as compared with a dielectric (including a sapphire substrate and a support member for fixing the substrate) used in the conventional superconductor thin film probe antenna. Moreover, the magnetic susceptibility of the metal wire (Cu) forming the superconductor is lower than that of a dielectric substrate, and concurrently the volume of the metal wire is sufficiently smaller than that of the dielectric (including the sapphire substrate and the support member for fixing the substrate) used in the conventional superconducting thin film probe antenna. As a result, the configuration of the third embodiment (using the sapphire bobbin and the Cu wire) can greatly suppress a magnetic moment induced by members other than the superconductor required for the antenna configuration, as compared with the configuration of the conventional superconducting thin film probe antenna (using the sapphire substrate and the support member for fixing the substrate).

Furthermore, in the conventional superconducting thin film probe antenna, plural dielectric substrates are discretely disposed in a uniform magnetic field space. By contrast, in the third embodiment, the antenna can be formed by using a single cylindrical bobbin of excellent symmetry. With this antenna configuration, a distribution pattern of an error magnetic field by the dielectric is simplified, and it becomes easy to ensure the magnetic homogeneity by shimming.

With the above effects, the configuration of the third embodiment can improve the magnetic homogeneity of the static magnetic field in the sample space by one digit, as compared with the conventional superconducting thin film probe antenna. As a result, the present invention makes it possible to provide a probe antenna that has a very high Q factor resulting from the distinctive low loss property of a superconductor, and that prevents impairment of the magnetic homogeneity of the static magnetic field in a sample space.

The resonance characteristics of the probe antenna according to the third embodiment are evaluated in liquid helium (4.2 K). The result of the evaluation shows that the Q factor at frequencies of 300 to 600 MHz is improved by a factor of two to four, as compared with the conventional probe antenna made of a normal conductor. Accordingly, using the probe antenna of this configuration for the NMR spectrometer achieves a great improvement in the measurement sensitivity.

In the third embodiment, the MgB₂ thin film is used for the superconducting layer 81 of the wire for each antenna coil. It is obvious that the same result can be obtained also in a similar configuration using, as a superconductor, a Nb alloy (Nb₃Sn or the like), or an oxide high-temperature superconductor such as YBCO. Moreover, it is obvious that a similar configuration may be obtained by using, for the metal wire 65 of the wire for the antenna coil, a diamagnetic metal (Ag, Au, or the like) other than Cu, or a paramagnetic metal (Al, Ta, Pt, Ti, Nb, Rh, or the like). Moreover, although sapphire is used for the cylindrical bobbin 61 and the support plates 27-1 and 27-2 in the third embodiment, it is obvious that aluminum nitride (AlN) may be used instead of the sapphire to obtain the same result.

### Fourth Embodiment

The fourth embodiment proposes an NMR spectrometer including a saddle-shaped probe antenna. A wire used for the probe antenna has a structure in which a superconducting layer is formed on the surface of a metal wire as shown in FIG. 2, as in the cases of the first to third embodiments. In the fourth embodiment, a Cu wire for 1 mm diameter is used for a metal wire 65, and a superconducting magnesium diboride (MgB₂) thin film of 1 μm thickness is formed on the surface of the metal wire 65 by evaporation method.

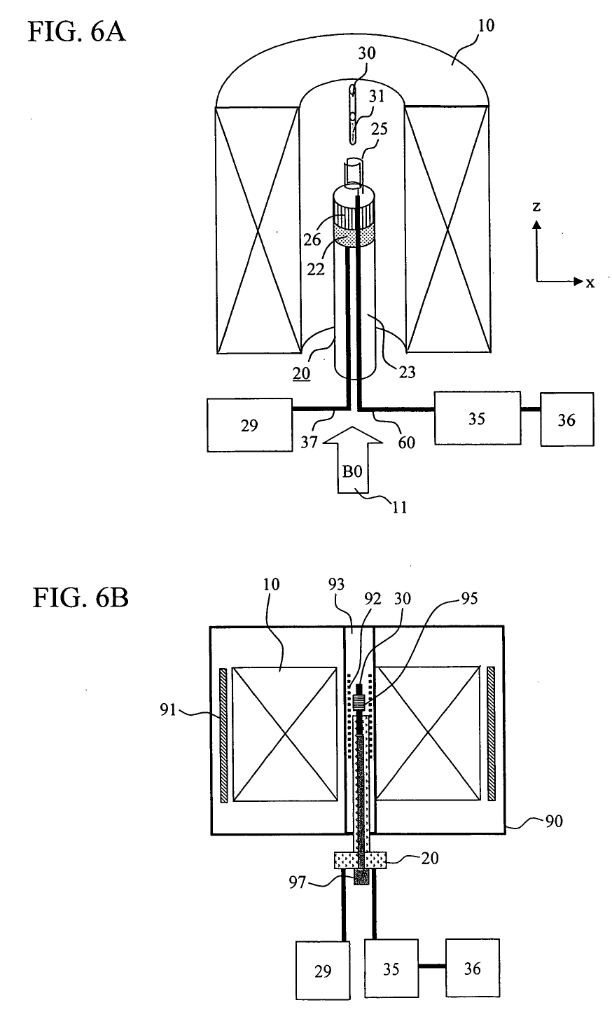

The saddle-shaped probe antenna may be employed in an NMR spectrometer which produces a static magnetic field (B₀) in the vertical direction by using a cylindrical magnet. FIG. 6A shows the configuration of the NMR spectrometer which produces a static magnetic field in the vertical direction. In the probe antenna, a cylindrical superconducting magnet 10 produces a uniform magnetic field 11 along the center axis. A cryogenic probe 20 and a sample tube 30 with a sample 31 housed therein are inserted from the same direction as that of the static magnetic field (e.g., the direction of the z-axis in FIG. 6A). The cryogenic probe 20 is constituted of a probe antenna 25, a heat exchanger 22, a cold gas line 37, a probe tip stage 26, and a probe housing 23. The heat exchanger 22 is provided at the end portion of a cryocooler 29 that acts as a cold source. Through the cold gas line 37, He gas cooled by the cryocooler 29 is circulated to cool the heat exchanger 22. The probe tip stage 26 is cooled by the heat exchanger 22. The probe antenna 25, the heat exchanger 22, the cryocooler 29, the cold gas line 37, and the probe tip stage 26 are connected with one another in the probe housing 23. In addition, a spectrometer 35 transmits an RF signal to the probe antenna 25 through the signal line 60, then receives and analyzes an RF signal sent from the sample 31, and outputs the result of the measurement to a display device 36, which in turn displays the result. Moreover, an unillustrated gradient coil for producing a gradient magnetic field in a sample space is disposed outside the probe antenna 25.

FIG. 6B is a schematic view showing in more detail the principal constituent part of the NMR spectrometer to which the present invention is applied. The superconducting magnet 10 is installed in a cryostat 90 filled with liquid helium, and a superconducting shim coil 91 for correcting the static magnetic field is disposed around the outer side of the superconducting magnet 10. A bore 93 is provided at the center of the cryostat 90 of the magnet, while a room-temperature shim coil 92 is provided inside the bore 93. In addition, a sample rotating/sample temperature controlling system 97 is installed in the bore 93. The sample rotating/sample temperature controlling system 97 rotates the sample tube 30 by blowing gas, and concurrently regulates the temperature of the sample 31 by feeding a temperature regulating gas. The sample tube 30 is inserted inside the sample rotating/sample temperature controlling system 97 while being held by a spinner 95.

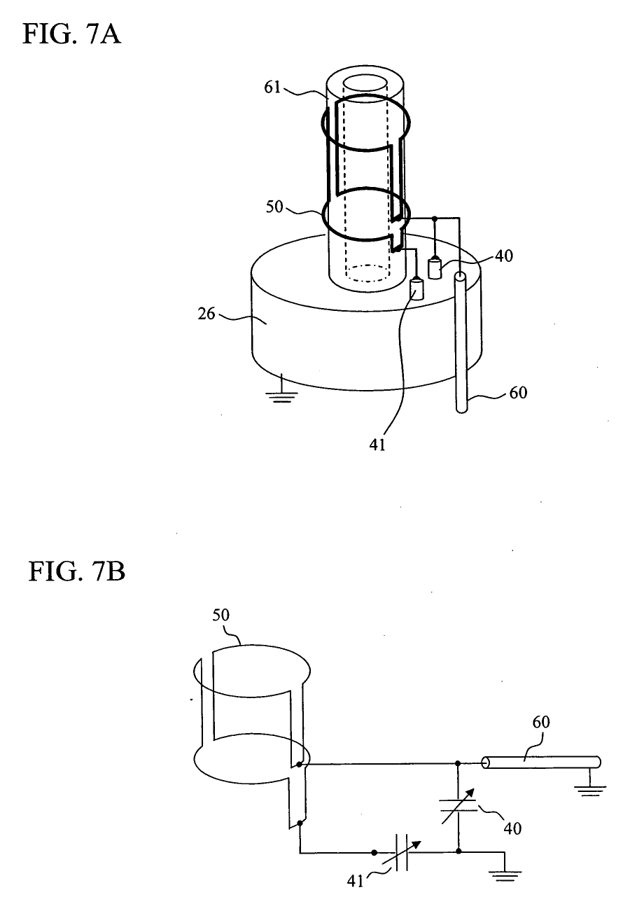

FIG. 7A is a perspective view schematically showing the saddle-shaped probe antenna according to the fourth embodiment mounted on the cryogenic probe 20. FIG. 7B schematically shows electrical connection of the saddle-shaped probe antenna according to the fourth embodiment. A cylindrical bobbin 61 is fixed on the same axis as that of the probe tip stage 26, and an antenna coil 50 is wound around the cylindrical bobbin 61. The antenna coil 50 is connected, at a first end thereof, to a matching trimmer capacitor 40 and the signal line 60, and is also connected, at a second end thereof, to a tuning trimmer capacitor 41. Electrodes, having no connections to the antenna coil 50, of the respective trimmer capacitors 40 and 41, and a coating on the signal line 60 are electrically and mechanically connected to the probe tip stage 26 made of a metallic material. The capacitances of the two trimmer capacitors 40 and 41 are adjusted so that the impedance of the antenna at its resonance peak can be matched to 50Ω at a predetermined resonance frequency. The cylindrical bobbin 61 is made of sapphire (Al₂O₃). In the fourth embodiment, the diameter and the height of the antenna coil 50 are set to 8 mm and 20 mm, respectively.

The probe tip stage 26 is cooled to low temperature by being thermally connected to the heat exchanger 22 at the end of the cryocooler 29 that acts as the cold source, which is not shown in FIG. 7A. Additionally, the probe tip stage 26 and the cylindrical bobbin 61 are likewise thermally connected to each other. Accordingly, the antenna coil 50 is cooled to the cryogenic temperature by heat transfer through the cylindrical bobbin 61.

In the probe antenna according to the fourth embodiment, the superconducting thin film of a low resistance is disposed on the surface of the wire for the antenna coil which a radio-frequency current converges to and passes through upon detection of a signal. With this configuration, it is possible to reduce a resistive loss, and to thus improve a Q factor, as compared with an antenna coil using a normal conductor.

In addition, the dielectric (the sapphire bobbin) used in the fourth embodiment can be greatly reduced in volume as compared with a dielectric (including a sapphire substrate and a support member for fixing the substrate) used in the conventional superconducting thin film probe antenna. Moreover, the magnetic susceptibility of the metal wire (Cu) forming the superconductor is lower than that of a dielectric substrate, and concurrently the volume of the metal wire is sufficiently smaller than that of the dielectric (including the sapphire substrate and the support member for fixing the substrate) used in the conventional superconducting thin film probe antenna. As a result, the configuration of the fourth embodiment (using the sapphire bobbin and the Cu wire) can greatly suppress a magnetic moment induced by members other than the superconductor required for the antenna configuration, as compared with the configuration of the conventional superconducting thin film probe antenna (using the sapphire substrate and the support member for fixing the substrate).

Furthermore, in the conventional superconducting thin film probe antenna, plural dielectric substrates are discretely disposed in a uniform magnetic field space. By contrast, in the fourth embodiment, the antenna can be formed by using a single cylindrical bobbin of excellent symmetry. With this antenna configuration, a distribution pattern of an error magnetic field by the dielectric is simplified, and it becomes easy to ensure the magnetic homogeneity by shimming.

With the above effects, the configuration of the fourth embodiment can improve the magnetic homogeneity of the static magnetic field in the sample space by one digit, as compared with the conventional superconducting thin film probe antenna. As a result, the present invention makes it possible to provide a probe antenna that has a very high Q factor resulting from the distinctive low loss property of a superconductor, and that prevents impairment of the magnetic homogeneity of the static magnetic field in a sample space.

The resonance characteristics of the probe antenna according to the fourth embodiment are evaluated in liquid helium (4.2 K). The result of the evaluation shows that the Q value at frequencies of 300 to 600 MHz is improved by a factor of two to four, as compared with the conventional probe antenna made of a normal conductor. Accordingly, using the probe antenna of this configuration for the NMR spectrometer achieves a great improvement in the measurement sensitivity.

In the fourth embodiment, the MgB2 film is used for the superconducting layer 81 of the wire for the antenna coil. It is obvious that the same result can be obtained also in a similar configuration using, as a superconductor, a Nb alloy (Nb₃Sn or the like), or an oxide high-temperature superconductor such as YBCO. Moreover, it is obvious that a similar configuration may be obtained by using, for the metal wire 65 of the wire for the antenna coil, a diamagnetic metal (Ag, Au, or the like) other than Cu, or a paramagnetic metal (Al, Ta, Pt, Ti, Nb, Rh, or the like). Moreover, although sapphire is used for the cylindrical bobbin 61 in the fourth embodiment, it is obvious that aluminum nitride (AlN) may be used instead of the sapphire to obtain the same result.

### Fifth Embodiment

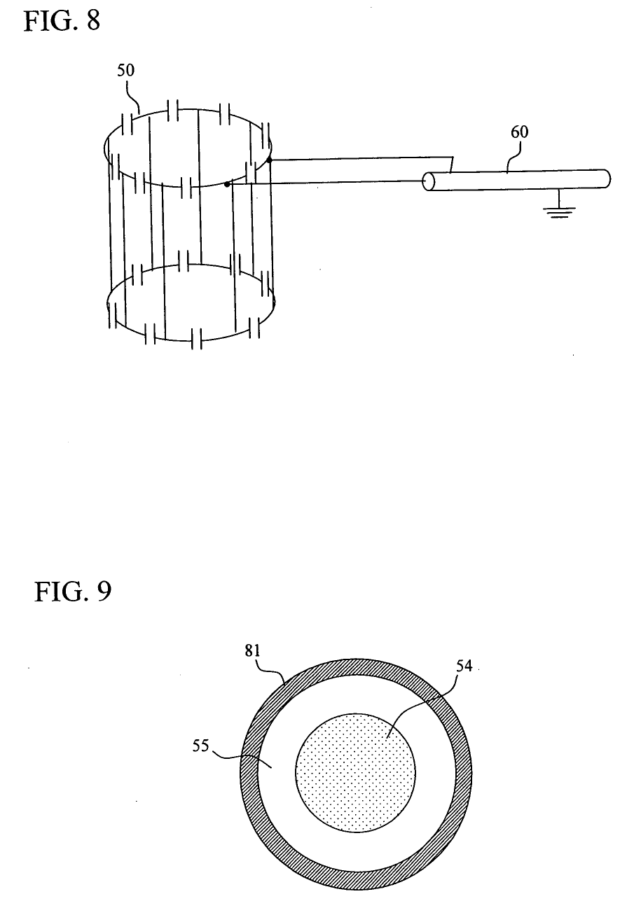

The fifth embodiment proposes an NMR spectrometer including a birdcage-shaped probe antenna. The basic configuration of the NMR spectrometer according to the fifth embodiment is the same as that of the fourth embodiment. A cylindrical magnet is used to produce a static magnetic field in the vertical direction. FIG. 8 schematically shows electrical connection of the birdcage-shaped probe antenna according to the fifth embodiment. A wire used for the probe antenna has a structure in which a superconducting layer is formed on the surface of a metal wire as shown in FIG. 2, as in the cases of the first to fourth embodiments. In the fifth embodiment, a Cu wire for 1 mm diameter is used for a metal wire 65, and a superconducting magnesium diboride (MgB₂) thin film of 1 μm thickness is formed on the surface of the metal wire 65 by evaporation method. In addition, the diameter and the height of the antenna coil are set to 8 mm and 20 mm, respectively. A manner of how the antenna coil is mounted on a cryogenic probe 20, and a cooling method, of the fifth embodiment are the same as those of the fourth embodiment.

In the probe antenna according to the fifth embodiment, the superconducting thin film of a low resistance is disposed on the surface of the wire for the antenna coil which a radio-frequency current converges to and passes through upon detection of a signal. With this configuration, it is possible to reduce a resistive loss, and to thus improve a Q factor, as compared with an antenna coil using a normal conductor.

In addition, the dielectric (the sapphire bobbin) used in the fifth embodiment can be greatly reduced in volume as compared with a dielectric (including a sapphire substrate and a support member for fixing the substrate) used in the conventional superconducting thin film probe antenna. Moreover, the magnetic susceptibility of the metal wire (Cu) forming the superconductor is lower than that of a dielectric substrate, and concurrently the volume of the metal wire is sufficiently smaller than that of the dielectric (including the sapphire substrate and the support member for fixing the substrate) used in the conventional superconducting thin film probe antenna. As a result, the configuration of the fifth embodiment (using the sapphire bobbin and the Cu wire) can greatly suppress a magnetic moment induced by members other than the superconductor required for the antenna configuration, as compared with the configuration of the conventional superconducting thin film probe antenna (using the sapphire substrate and the support member for fixing the substrate).

Furthermore, in the conventional superconducting thin film probe antenna, plural dielectric substrates are discretely disposed in a uniform magnetic field space. By contrast, in the fifth embodiment, the antenna can be formed by using a single cylindrical bobbin of excellent symmetry. With this antenna configuration, a distribution pattern of an error magnetic field by the dielectric is simplified, and it becomes easy to ensure the magnetic homogeneity by shimming.

With the above effects, the configuration of the fifth embodiment can improve the magnetic homogeneity of the static magnetic field in the sample space by one digit, as compared with the conventional superconducting thin film probe antenna. As a result, the present invention makes it possible to provide a probe antenna that has a very high Q factor resulting from the distinctive low loss property of a superconductor, and that prevents impairment of the magnetic homogeneity of the static magnetic field in a sample space.

The resonance characteristics of the probe antenna according to the fifth embodiment are evaluated in liquid helium (4.2 K). The result of the evaluation shows that the Q value at frequencies of 300 to 600 MHz is improved by a factor of two to four, as compared with the conventional probe antenna made of a normal conductor. Accordingly, using the probe antenna of this configuration for the NMR spectrometer achieves a great improvement in the measurement sensitivity.

In the fifth embodiment, the MgB₂ thin film is used for the superconducting layer 81 of the wire for the antenna coil. It is obvious that the same result can be obtained also in a similar configuration using, as a superconductor, a Nb alloy (Nb₃Sn or the like), or an oxide high-temperature superconductor such as YBCO. In addition, it is obvious that a similar configuration may be obtained by using, for the metal wire 65 of the wire for the antenna coil, a diamagnetic metal (Ag, Au, or the like) other than Cu, or a paramagnetic metal (Al, Ta, Pt, Ti, Nb, Rh, or the like). Moreover, although sapphire is used for the cylindrical bobbin 61 in the fifth embodiment, it is obvious that aluminum nitride (AlN) may be used instead of the sapphire to obtain the same result.

### Sixth Embodiment

The sixth embodiment proposes an NMR spectrometer which can further improve the magnetic transparency of a probe antenna coil.

FIG. 9 schematically shows a cross-sectional structure of a wire for an antenna coil according to the sixth embodiment. A superconducting layer 81 is formed on the surface of a composite metal wire made of two kinds of metals: a paramagnetic metal 54 and a diamagnetic metal 55. Combining the paramagnetic metal 54 and the diamagnetic metal 55 cancels magnetization of both metals 54 and 55, thus improving the magnetic transparency of the wire. In the sixth embodiment, Al, Cu, and superconducting magnesium diboride (MgB₂) are used respectively for the paramagnetic metal 54, the diamagnetic metal 55, and the superconducting layer 81. In order to cancel the magnetization of the paramagnetic metal (Al) 54 and the diamagnetic metal (Cu) 55 at the operating temperature (approximately 5 K) of the antenna coil, the magnetic susceptibilities of both metals at a low temperature are taken into consideration. With this consideration, the diameter of the paramagnetic metal (Al) 54 is set to 0.34 mm, while the diameter of the entire composite metal wire is set to 1 mm. Then, the MgB₂ thin film of 1 μm thickness is formed on the surface of the composite metal wire by evaporation method.

The wire for the antenna coil according to the sixth embodiment may be employed in any of the NMR spectrometer including the solenoidal-shaped probe antenna, the NMR spectrometer including the saddle-shaped probe antenna, and the NMR spectrometer including the birdcage-shaped probe antenna, whose specific configurations are shown in the first to fifth embodiments. In any of these NMR spectrometers, it is possible to achieve a great improvement in the measurement sensitivity by fabricating an antenna coil using the wire according to the sixth embodiment.

In the probe antenna according to the sixth embodiment, the superconducting thin film of a low resistance is disposed on the surface of the wire for the antenna coil which a radio-frequency current converges to and passes through upon detection of a signal. With this configuration, it is possible to reduce a resistive loss, and to thus improve a Q factor, as compared with an antenna coil using a normal conductor.

In addition, the dielectric (the sapphire bobbin) used in the sixth embodiment can be greatly reduced in volume as compared with a dielectric (including a sapphire substrate and a support member for fixing the substrate) used in the conventional superconductor thin film probe antenna. Moreover, the magnetic susceptibility of the metal wire (Cu) forming the superconductor is lower than that of a dielectric substrate, and concurrently the volume of the metal wire is sufficiently smaller than that of the dielectric (including the sapphire substrate and the support member for fixing the substrate) used in the conventional superconducting thin film probe antenna. As a result, the configuration of the sixth embodiment (using the sapphire bobbin and the Cu wire) can greatly suppress a magnetic moment induced by members other than the superconductor required for the antenna configuration, as compared with the configuration of the conventional superconducting thin film probe antenna (using the sapphire substrate and the support member for fixing the substrate).

Furthermore, in the conventional superconducting thin film probe antenna, plural dielectric substrates are discretely disposed in a uniform magnetic field space. By contrast, in the sixth embodiment, the antenna can be formed by using a single cylindrical bobbin of excellent symmetry. With this antenna configuration, a distribution pattern of an error magnetic field by the dielectric is simplified, and it becomes easy to ensure the magnetic homogeneity by shimming.

With the above effects, the configuration of the sixth embodiment can improve the magnetic homogeneity of the static magnetic field in the sample space by one digit, as compared with the conventional superconducting thin film probe antenna. As a result, the present invention makes it possible to provide a probe antenna that has a very high Q factor resulting from the distinctive low loss property of a superconductor, and that prevents impairment of the magnetic homogeneity of the static magnetic field in a sample space.

In the sixth embodiment, the MgB₂ thin film is used for the superconducting layer 81 of the wire for the antenna coil. It is obvious that the same result can be obtained also in a similar configuration using, as a superconductor, a Nb alloy (Nb₃Sn or the like), or an oxide high-temperature superconductor such as YBCO. Moreover, it is obvious that a similar configuration may be obtained by using, for the paramagnetic metal 54 of the wire for the antenna coil, a metal (Ta, Pt, Ti, Nb, Rh, or the like) other than Al. On the other hand, it is also obvious that a similar configuration may be obtained by using, for the diamagnetic metal 55 of the wire for the antenna coil, a metal (Ag, Au, or the like) other than Cu. Moreover, the sixth embodiment has shown the wire for a three-layer structure in which the superconducting layer 81 is formed on the surface of the composite metal wire made of a single layer of the paramagnetic metal 54 and a single layer of the diamagnetic metal 55. However, needless to say, it is also possible to form a wire of a structure (a four-layer structure, a five-layer structure, or the like) in which the superconducting layer 81 is formed on the surface of a metallic body formed by combining more layers of the paramagnetic metal 54 and the diamagnetic metal 55.

### Seventh Embodiment

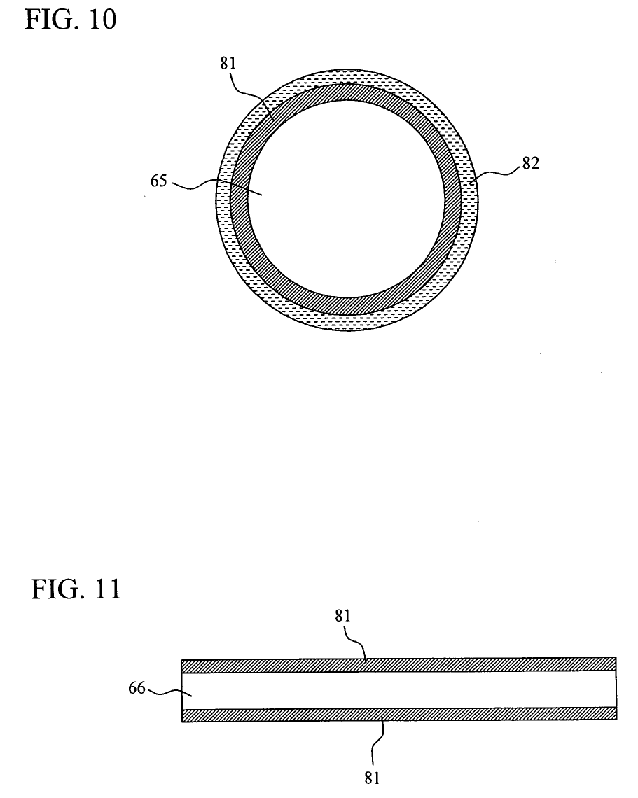

FIG. 10 schematically shows a cross-sectional structure of a wire for an antenna coil according to the seventh embodiment. The wire has a three-layer structure formed of: a metal wire 65 that is a base material; a superconducting layer 81 formed on the surface of the metal wire; and an insulating layer 82 formed on the surface of the superconducting layer 81. A Cu wire for 1 mm diameter is used as the metal wire 65. Thereafter, a superconducting magnesium diboride (MgB₂) thin film of 1 μm thickness is formed on the surface of the metal wire 65 by evaporation method. Moreover, an AlN insulating film of a 500 nm thickness is formed on the surface of the MgB₂ thin film by sputtering. The AlN insulating layer 82 formed on the outermost surface acts as an insulating film for the superconducting layer 81. Accordingly, since the superconducting layer 81 is prevented from being exposed to the ambient air, it is possible to suppress degradation in the superconducting characteristic of the superconducting layer 81.

The wire for the antenna coil according to the seventh embodiment may be employed in any of the NMR spectrometer including the solenoidal-shaped probe antenna, the NMR spectrometer including the saddle-shaped probe antenna, and the NMR spectrometer including the birdcage-shaped probe antenna, whose specific configurations are shown in the first to fifth embodiments. In any of these NMR spectrometers, it is possible to achieve a great improvement in the measurement sensitivity by fabricating an antenna coil using the wire according to the seventh embodiment.

In the probe antenna according to the seventh embodiment, the superconducting thin film of a low resistance is disposed on the surface of the wire for the antenna coil which a radio-frequency current converges to and passes through upon detection of a signal. With this configuration, it is possible to reduce a resistive loss, and to thus improve a Q factor, as compared with an antenna coil using a normal conductor.

In addition, the dielectric (the sapphire bobbin) used in the seventh embodiment can be greatly reduced in volume as compared with a dielectric (including a sapphire substrate and a support member for fixing the substrate) used in the conventional superconductor thin film probe antenna. Moreover, the magnetic susceptibility of the metal wire (Cu) forming the superconductor is lower than that of a dielectric substrate, and concurrently the volume of the metal wire is sufficiently smaller than that of the dielectric (including the sapphire substrate and the support member for fixing the substrate) used in the conventional superconducting thin film probe antenna. As a result, the configuration of the seventh embodiment (using the sapphire bobbin and the Cu wire) can greatly suppress a magnetic moment induced by members other than the superconductor required for the antenna configuration, as compared with the configuration of the conventional superconducting thin film probe antenna (using the sapphire substrate and the support member for fixing the substrate).

Furthermore, in the conventional superconducting thin film probe antenna, plural dielectric substrates are discretely disposed in a uniform magnetic field space. By contrast, in the seventh embodiment, the antenna can be formed by using a single cylindrical bobbin of excellent symmetry. With this antenna configuration, a distribution pattern of an error magnetic field by the dielectric is simplified, and it becomes easy to ensure the magnetic homogeneity by shimming.

With the above effects, the configuration of the seventh embodiment can improve the magnetic homogeneity of the static magnetic field in the sample space by one digit, as compared with the conventional superconducting thin film probe antenna. As a result, the present invention makes it possible to provide a probe antenna that has a very high Q factor resulting from the distinctive low loss property of a superconductor, and that prevents impairment of the magnetic homogeneity of the static magnetic field in a sample space.

In the seventh embodiment, the MgB₂ thin film is used for the superconducting layer 81 of the wire for the antenna coil. It is obvious that the same result can be obtained also in a similar configuration using, as a superconductor, a Nb alloy (Nb₃Sn or the like), or an oxide high-temperature superconductor such as YBCO. In addition, it is obvious that a similar configuration may be obtained by using, for the metal wire 65 of the wire for the antenna coil, a diamagnetic metal (Ag, Au, or the like) other than Cu, or a paramagnetic metal (Al, Ta, Pt, Ti, Nb, Rh, or the like). On the other hand, it is also obvious that a similar configuration may be obtained by using, as the material for the insulating layer 82, an insulator (Al₂O₃, or the like) other than AlN. Moreover, although a single kind of metal (Cu) is used for the base metal of the wire in the seventh embodiment, it is needless to say that a similar configuration may be obtained by using a metal complex of a multi-layer structure formed of a paramagnetic metal and a diamagnetic metal as shown in the sixth embodiment.

### Eighth Embodiment

The eighth embodiment proposes an NMR spectrometer using a metal foil for a wire for an antenna coil. FIG. 11 schematically shows a cross-sectional structure of the wire for the antenna coil according to the eighth embodiment. The wire has a three-layer structure formed of a metal foil 66 that is a base material, and superconducting layers 81 formed respectively on both surfaces of the metal foil 66. A Cu foil of 1 mm width and 30 μm thickness is used as the metal foil 66, and a superconducting magnesium diboride (MgB₂) thin film of 1 μm thickness is formed on each surface of the metal foil 66 by evaporation method.

The wire for the antenna coil according to the eighth embodiment may be employed in any of the NMR spectrometer including the solenoidal-shaped probe antenna, the NMR spectrometer including the saddle-shaped probe antenna, and the NMR spectrometer including the birdcage-shaped probe antenna, whose specific configurations are shown in the first to fifth embodiments. The antenna coil is formed by winding the metal foil 66 around a sapphire bobbin, so that one of the surfaces, each having the superconducting layer 81 formed thereon, of the metal foil 66 (the surfaces, having a longer width, of the metal foil 66) abuts on the surface of the sapphire bobbin. Note that, when the antenna coil is to be employed in the saddle-shaped antenna shown in the fourth embodiment, or the birdcage-shaped antenna shown in the fifth embodiment, the antenna coil may be alternatively formed by: cutting out the metal foil 66 into the shape of the antenna in advance; then forming the superconducting layer 81 on each surface of the metal foil 66; and lastly bonding the formed metal complex to the surface of the sapphire bobbin. Using the wire according to the eighth embodiment makes it possible to achieve a great improvement in the measurement sensitivity with the effects described in the first to fifth embodiments, in any of the NMR spectrometers using the solenoidal-shaped antenna, the saddle-shaped antenna, and the birdcage-shaped antenna, respectively.

In the eighth embodiment, the MgB₂ thin film is used for each superconducting layer 81 of the wire for the antenna coil. It is obvious that the same result can be obtained also in a similar configuration using, as a superconductor, a Nb alloy (Nb₃Sn or the like), or an oxide high-temperature superconductor such as YBCO. In addition, it is obvious that a similar configuration may be obtained by using, for the metal foil 66 of the wire for the antenna coil, a diamagnetic metal (Ag, Au, or the like) other than Cu, or a paramagnetic metal (Al, Ta, Pt, Ti, Nb, Rh, or the like).

### Ninth Embodiment

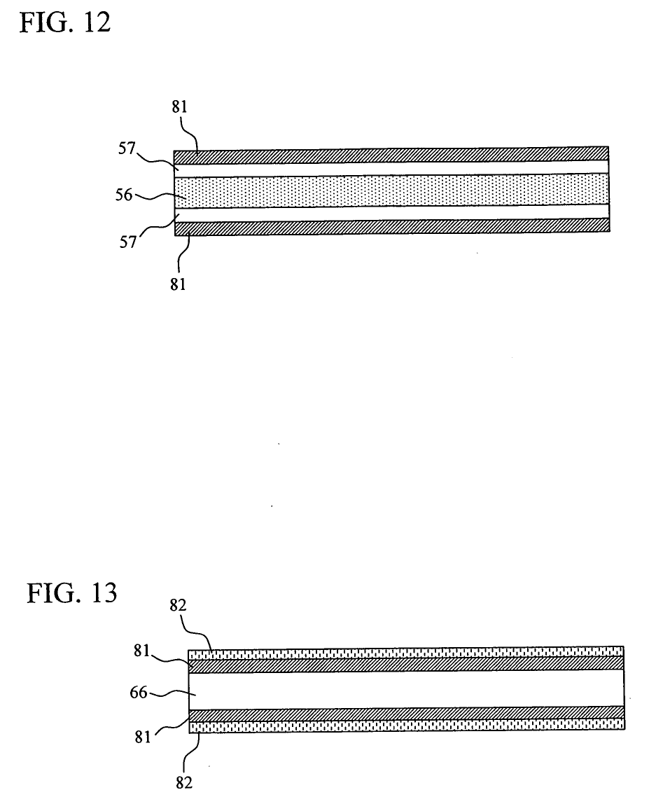

The ninth embodiment proposes an NMR spectrometer which uses a metal foil for a wire for an antenna coil as in the case of the eighth embodiment. Concurrently, the ninth embodiment proposes the NMR spectrometer which can further improve the magnetic transparency of the probe antenna coil. FIG. 12 schematically shows a cross-sectional structure of the wire for the antenna coil according to the ninth embodiment. Superconducting layers 81 are formed respectively on the surfaces of a composite metal foil formed of two kinds of metal foils--a paramagnetic metal foil 56 and diamagnetic metal foils 57. Laminating the paramagnetic metal foil 56 and the diamagnetic metal foils 57 cancels magnetization of these metal foils 56 and 57, thus improving the magnetic transparency of the wire. In the ninth embodiment, an Al foil, a Cu foil, and a superconducting magnesium diboride (MgB₂) thin film are used respectively for the paramagnetic metal foil 56, each diamagnetic metal foil 57, and the superconducting layer 81. In order to cancel the magnetization of the paramagnetic metal foil (Al) 56 and the diamagnetic metal foils (Cu) 57 at the operation temperature (approximately 5 K) of the antenna coil, the magnetic susceptibilities of both metals at a low temperature are taken into consideration. With this consideration, the thicknesses of the paramagnetic metal foil (Al) 56, the diamagnetic metal foil (Cu) 57, and the entire composite metal foil are set to 8.7 μm, 21.3 μm, and 30 μm, respectively. In addition, the composite metal foil is formed to have a 1 mm width, and then the MgB₂ thin film of 1 μm thickness is formed on each surface of the composite metal foil by evaporation method.

The wire for the antenna coil according to the ninth embodiment may be employed in any of the NMR spectrometer including the solenoidal-shaped probe antenna, the NMR spectrometer including the saddle-shaped probe antenna, and the NMR spectrometer including the birdcage-shaped probe antenna, whose specific configurations are shown in the first to fifth embodiments. The antenna coil is formed by winding the composite metal foil around a sapphire bobbin, so that one of the surfaces, having the superconducting layers 81 formed respectively thereon, of the composite metal foil (the surfaces, having a longer width, of the composite metal foil) abuts on the surface of the sapphire bobbin. Note that, when the antenna coil is employed in the saddle-shaped antenna shown in the fourth embodiment, or the birdcage-shaped antenna shown in the fifth embodiment, the antenna coil may be alternatively formed by: cutting out the composite metal foil into the shape of the antenna in advance, then forming the superconducting layers 81 respectively on the surfaces of the composite metal foil, and lastly bonding the formed metal complex to the surface of the sapphire bobbin. Using the wire according to the ninth embodiment makes it possible to achieve a great improvement in the measurement sensitivity with the effects described in the first to fifth embodiments, in any of the NMR spectrometers including the solenoid-shaped antenna, the saddle-shaped antenna, and the birdcage-shaped antenna, respectively.

In the ninth embodiment, the MgB₂ thin film is used for each superconducting layer 81 of the wire for the antenna coil. It is obvious that the same result can be obtained also in a similar configuration using, as a superconductor, a Nb alloy (Nb₃Sn or the like), or an oxide high-temperature superconductor such as YBCO. In addition, it is obvious that a similar configuration may be obtained by using, for the paramagnetic metal 56 of the wire for the antenna coil, a metal (Ta, Pt, Ti, Nb, Rh, or the like) other than Al. Moreover, it is also obvious that a similar configuration may be obtained by using, for the diamagnetic metal foil 57 of the wire for the antenna coil, a metal (Ag, Au, or the like) other than Cu. Furthermore, the ninth embodiment has shown the wire of a five-layer structure in which the superconducting layers 81 are formed respectively on the surfaces of the composite metal foil formed by laminating the diamagnetic metal foils 57 and the paramagnetic metal foil 56 sandwiched between the diamagnetic metal foils 57. However, needless to say, it is also possible to form a wire of a structure (a seven-layer structure, a nine-layer structure, or the like) in which superconducting layers 81 are formed respectively on the surfaces of a composite metal foil formed by laminating more layers of a paramagnetic metal foil 56 and a diamagnetic metal foil 57.

### Tenth Embodiment

The tenth embodiment proposes an NMR spectrometer using a metal foil for a wire for an antenna coil as in the case of the eighth embodiment. FIG. 13 schematically shows a cross-sectional structure of the wire for the antenna coil according to the tenth embodiment. The wire has a five-layer structure formed of a metal foil 66 that is a base material, superconducting layers 81 formed respectively on the surfaces of the metal foil 66, and insulating layers 82 formed respectively on the outer surfaces of the corresponding superconducting layers 81. A Cu foil of 1 mm width and 30 μm thickness is used as the metal foil 66. A superconducting magnesium diboride (MgB₂) thin film of 1 μm thickness is formed on each surface of the metal foil 66 by evaporation method. Then, an AlN insulating film of a 500 nm thickness is formed on the outer surface of each MgB₂ thin film by sputtering. The insulating layers 82 formed on the outermost surfaces act as insulating films for the corresponding superconducting layers 81. Accordingly, since the superconducting layers 81 are prevented from being exposed to the ambient air, it is possible to suppress degradation in the superconducting characteristic of the superconducting layers 81.

The wire for the antenna coil according to the tenth embodiment may be employed in any of the NMR spectrometer including the solenoidal-shaped probe antenna, the NMR spectrometer including the saddle-shaped probe antenna, and the NMR spectrometer including the birdcage-shaped probe antenna, whose specific configurations are shown in the first to fifth embodiments. The antenna coil is formed by winding the metal foil 66 around a sapphire bobbin, so that one of the surfaces, each having the superconducting layer 81 and the insulating layer 82 formed thereon, of the metal foil 66 (the surface, having a longer width, of the metal foil 66) abuts on the surface of the sapphire bobbin. Note that, when the antenna coil is to be employed in the saddle-shaped antenna shown in the fourth embodiment, or the birdcage-shaped antenna shown in the fifth embodiment, the antenna coil may be alternatively formed by: cutting out the metal foil 66 into the shape of the antenna in advance, then sequentially forming the superconducting layer 81 and the insulating layer 82 on each surface of the metal foil 66, and lastly bonding the formed composite metal foil to the surface on the sapphire bobbin. Using the wire according to the tenth embodiment makes it possible to achieve a great improvement in the measurement sensitivity with the effects described in the first to fifth embodiments, in any of the NMR spectrometers including the solenoid-shaped antenna, the saddle-shaped antenna, and the birdcage-shaped antenna, respectively.

In any of these above NMR spectrometers, it is possible to achieve a great improvement in the measurement sensitivity by fabricating an antenna coil using the wire according to the tenth embodiment.

In the tenth embodiment, the MgB₂ thin film is used for each superconducting layer 81 of the wire for the antenna coil. It is obvious that the same result can be obtained also in a similar configuration using, as a superconductor, a Nb alloy (Nb₃Sn or the like), or an oxide high-temperature superconductor such as YBCO. In addition, it is obvious that a similar configuration may be obtained by using, for the metal foil 66 of the wire for the antenna coil, a diamagnetic metal (Ag, Au, or the like) other than Cu, or a paramagnetic metal (Al, Ta, Pt, Ti, Nb, Rh, or the like). On the other hand, it is also obvious that a similar configuration may be obtained by using, as the material for the insulating layers 82, an insulator (Al₂O₃, or the like) other than AlN. Moreover, although a single kind of metal (Cu) is used for the metal foil 66 of the wire for the antenna coil in the tenth embodiment, it is needless to say that a similar configuration may be obtained by using a metal complex of a multi-layer structure formed of a paramagnetic metal foil and diamagnetic metal foils as shown in the ninth embodiment.

It should be noted that the explanation of the reference numerals in the drawings is given below.

### Explanation of the Reference Numerals

10, 10-1, 10-2 . . . SUPERCONDUCTING MAGNET, 11 . . . UNIFORM MAGNETIC FIELD, 20 . . . CRYOGENIC PROBE, 22 . . . HEAT EXCHANGER, 23 . . . PROBE HOUSING, 25 . . . PROBE ANTENNA, 26 . . . PROBE TIP STAGE, 27-1, 27-2 . . . SUPPORT PLATE, 29 . . . CRYOCOOLER, 30 . . . SAMPLE TUBE, 31 . . . SAMPLE, 35 . . . SPECTROMETER, 36 . . . DISPLAY DEVICE, 37 . . . COLD GAS LINE, 45 . . . TAP LINE, 40, 41 . . . TRIMMER CAPACITOR, 50 . . . ANTENNA COIL, 54 . . . PARAMAGNETIC METAL, 55 . . . DIAMAGNETIC METAL, 56 . . . PARAMAGNETIC METAL FOIL, 57 . . . DIAMAGNETIC METAL FOIL, 60 . . . SIGNAL LINE, 61 . . . CYLINDRICAL BOBBIN, 65 . . . METAL WIRE, 66 . . . METAL FOIL, 81 . . . SUPERCONDUCTING LAYER, 82 . . . INSULATING LAYER, 90 . . . CRYOSTAT, 91 . . . SUPERCONDUCTING SHIM COIL, 92 . . . ROOM-TEMPERATURE SHIM COIL, 93 . . . BORE, 94 . . . SAMPLE ROTATING SYSTEM, 95 . . . SPINNER, 96 . . . SAMPLE TEMPERATURE CONTROLLING SYSTEM, 97 . . . SAMPLE ROTATING/SAMPLE TEMPERATURE CONTROLLING SYSTEM

What is claimed is:

1. An NMR spectrometer comprising:
a magnet which produce a uniform magnetic field;
a probe antenna which applies a radio-frequency signal to a sample placed in the uniform magnetic field, and which also receives a response signal from the sample;
a stage to which the probe antenna is fixed;
a heat exchanger which cools the stage to maintain the probe antenna at a low temperature;
a spectrometer which transmits the radio-frequency signal to the probe antenna, and which also analyzes the response signal received by the probe antenna; and
a signal line which connects the spectrometer and the probe antenna to each other, wherein
the probe antenna is formed of any one of a metal wire having a superconductor formed on the surface thereof, and a metal foil having a superconductor formed on the surface thereof.

2. The NMR spectrometer according to claim 1 wherein the probe antenna is disposed on the outer periphery of a cylindrical member.

3. The NMR spectrometer according to claim 1 wherein the shape of a coil of the probe antenna is any one of a solenoidal-shape, a saddle-shape, and a birdcage-shape.

4. The NMR spectrometer according to claim 1 wherein the one of a metal wire and a metal foil is formed of a single kind of material.

5. The NMR spectrometer according to claim 1 wherein the one of a metal wire and a metal foil is formed by combining a paramagnetic metallic material and a diamagnetic metallic material with each other.

6. The NMR spectrometer according to claim 1 wherein the superconductor is any one of a Nb-based superconductor, a copper-oxide superconductor, and magnesium diboride.

7. The NMR spectrometer according to claim 1 wherein an insulator is formed on a surface of the superconductor.
